(19) United States
(12) Patent Application Publication
(10) Pub. No.: US 2026/0018236 A1
(43) Pub. Date: Jan. 15, 2026

(54) SEMICONDUCTOR MEMORY DEVICE AND REFRESH CONTROL METHOD THEREOF

(71) Applicant: Winbond Electronics Corp., Taichung City (TW)

(72) Inventor: Hitoshi IKEDA, Yokohama (JP)

(73) Assignee: Winbond Electronics Corp., Taichung City (TW)

(21) Appl. No.: 19/266,436

(22) Filed: Jul. 11, 2025

(30) Foreign Application Priority Data
Jul. 12, 2024 (JP) 2024-112226

(51) Int. Cl. G11C 29/00

(52) U.S. Cl. CPC G11C 29/783; G11C 29/76; G11C 29/785

(57) ABSTRACT

Provided are a semiconductor memory device, a row redundancy circuit, and a control method of the semiconductor memory device for suppressing unnecessary power consumption. The semiconductor memory device includes a memory cell array and a row redundancy circuit. The memory cell array has a plurality of segments, each segment having a plurality of normal word lines and redundant word lines. The row redundancy circuit is configured to activate non-defective normal word lines and non-defective redundant word lines during a refresh operation. Activation and replacement of defective normal word lines and defective redundant word lines are not performed in each segment during the refresh operation.

### CROSS REFERENCE TO RELATED APPLICATIONS

This application claims priority of Japanese Patent Application No. 2024-112226, filed on Jul. 12, 2024, the entirety of which is incorporated by reference herein.

### BACKGROUND OF THE INVENTION

### Field of the Invention

The present invention relates to a semiconductor memory device and a refresh control method thereof, and in particular, it relates to a semiconductor memory device and a refresh control method thereof that reduces power consumption during refresh operations.

### Description of the Related Art

Dynamic random access memory (DRAM) is a semiconductor memory device that stores information by storing a charge in a capacitor. It is a volatile memory, which means that it loses the stored information when power is no longer supplied. Since DRAM memory cells use the charge stored in the capacitor to store information, a refresh operation must be performed periodically to prevent information loss due to leakage current. In other words, all memory cells must be refreshed before the information is lost due to leakage current, and the refresh cycle is determined by the specifications of the DRAM.

Recent advances in DRAM miniaturization have reduced memory cell capacity, resulting in shorter retention times and more frequent refresh operations. To address such issue, as disclosed in U.S. Pat. No. 9,269,458 (hereinafter referred to as patent document 1), in many DRAMs, the number of refresh operations can be reduced by activating (enabling) more word lines simultaneously during a refresh operation than during a normal operation (active operation). However, in the refresh operation, if the redundant memory cell region to which the redundant memory cell for replacement belongs and the normal memory cell region to which the normal memory cell that has not yet been replaced belongs are activated at the same time, it will lead to unnecessary power consumption.

Patent document 1 discloses a semiconductor device having a redundancy determination circuit that, in response to an event in which the normal memory cell that belongs to at least one memory block is being replaced by the redundant memory cell in a refresh mode, deactivates a normal cell area to which the normal memory cell that is a source of replacement belongs and activates a redundant cell area to which the redundant memory cell that is to be replaced belongs and a normal cell area to which the normal memory cell that is not being replaced belongs.

During the refresh operation, this kind of semiconductor device is inhibited from selecting a normal memory cell that belongs to the same memory mat as the redundant memory cell to be replaced to prevent destruction of data, but this lowers redundancy efficiency. Besides, in this scenario, the redundancy determination circuit issues one inhibit signal for N memory blocks with N word lines activated during refresh. As a result, if a word line in any block fails, all N corresponding redundant word lines to be replaced are activated at once, reducing redundancy efficiency by a factor of N.

### BRIEF SUMMARY OF THE INVENTION

In view of the aforementioned problems, the object of the present invention is to provide a semiconductor memory device and refresh control method thereof capable of suppressing unnecessary power consumption during the refresh operation and improving redundancy efficiency.

This semiconductor memory device of the present invention includes a memory cell array and a row redundancy circuit. The memory cell array has a plurality of segments. Each segment has a plurality of normal word lines and redundant word lines. The row redundancy circuit is configured to activate non-defective normal word lines and non-defective redundant word lines during a refresh operation. Activation and replacement of defective normal word lines and defective redundant word lines are not performed in each segment during the refresh operation.

The control method of the semiconductor memory device of the present invention includes the following steps. First, a memory cell array is configured to include a plurality of segments, each segment has a plurality of normal word lines and a plurality of redundant word lines. During a refresh operation, non-defective normal word lines and non-defective redundant word lines are activated by a row redundancy circuit, wherein activation and replacement of defective normal word lines and defective redundant word lines are not performed in each of the segments.

According to the present invention, power consumption during the refresh operation can be reduced by not activating or replacing defective word lines during the refresh operation, and the redundancy efficiency can be consistent as design.

### BRIEF DESCRIPTION OF THE DRAWINGS

The present invention can be more fully understood by reading the subsequent detailed description and examples with references made to the accompanying drawings, wherein:

FIG. 1 is an exemplary block diagram of a semiconductor memory device according to a first embodiment of the present invention.

FIG. 2 is a structural diagram showing a memory cell array.

FIG. 3 is a schematic diagram for explaining the relationship between a row redundancy circuit and a memory cell array.

FIG. 4 is a diagram for explaining the control of a row redundancy circuit.

FIG. 5 is a diagram for explaining a specific example of controlling a row redundancy circuit.

FIG. 6 is a schematic diagram showing the structure of a row redundant circuit.

FIG. 7 is a schematic diagram showing the structure of a normal word line control circuit of a row redundant circuit.

FIG. 8 is a schematic diagram showing the structure of a redundant word line control circuit of a row redundant circuit.

FIG. 9 is a diagram showing an alternative example of a normal word line control circuit of a row redundant circuit.

FIG. 10 is a diagram showing details of an alternative example of a normal word line control circuit of a row redundant circuit.

FIG. 11 is an exemplary timing diagram in an alternative example of a normal word line control circuit of a row redundant circuit.

### DETAILED DESCRIPTION OF THE INVENTION

The control circuit and semiconductor memory device related to certain embodiments of the present invention are explained with reference to the drawings. However, these embodiments are only an example and is not intended to limit the scope of the present invention. It should be noted that when the same element s or components are distinguished by position, etc., “_n” (n is an integer) will be added after the reference symbol to distinguish them.

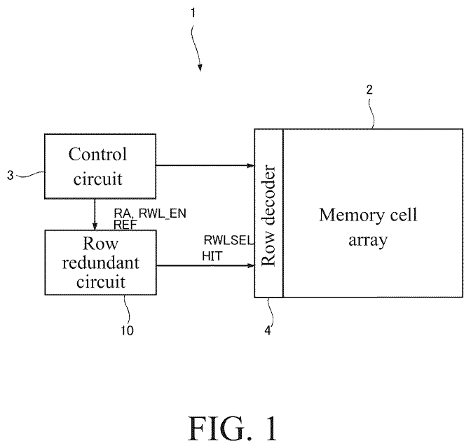

FIG. 1 shows an exemplary configuration of a semiconductor memory device according to a first embodiment of the present invention. In this embodiment, a semiconductor memory device 1 (for example, a DRAM) includes a row redundancy circuit 10. In addition, in this embodiment, in order to simplify the description, conventional configurations, such as an address buffer, a command decoder, a column decoder, an input/output interface unit, etc., provided in the semiconductor memory device are not shown.

The semiconductor memory device 1 may include a memory cell array 2, a control circuit 3, a row redundancy circuit 10, and a row decoder 4. In addition, the structure of the memory cell array 2 will be described later.

The control circuit 3 generates various control signals in synchronization with the internal clock signal, performs read/write operations on the memory cell array 2, and uses the row redundancy circuit 10, etc. to control the semiconductor memory device. In addition, in this embodiment, the active operation and refresh operation through the row redundancy circuit 10 are mainly described. The control circuit 3 outputs a refresh status signal REF indicating the refresh operation status to the row redundancy circuit 10, and activates the refresh status signal REF to a high level during the refresh operation.

In addition, the control circuit 3 includes an address circuit (not shown) therein to generate an address signal RA indicating a row address and a redundant enable signal RWL_EN. The redundant enable signal RWL_EN is a signal for activating a redundant word line. When the redundant enable signal RWL_EN is activated (high level), the redundant word line can be activated. The control circuit 3 outputs the address signal RA and the redundant enable signal RWL_EN to the row redundancy circuit 10.

The row redundancy circuit 10 of the present embodiment is configured to control the activation/deactivation of the normal word line and the redundant word line of the memory cell array 2. The row redundancy circuit 10 generates an inhibit signal HIT and a select signal RWLSEL based on the refresh status signal REF, the address signal RA and the redundant enable signal RWL_EN. The inhibit signal HIT is a signal for deactivating the normal word line or the redundant word line. When the inhibit signal HIT is generated at a high level, the activation of the normal word line or the redundant word line is inhibited, and therefore the normal word line or the redundant word line is deactivated (low level). The select signal RWLSEL is a signal for replacing the normal word line with a redundant word line. When the select signal RWLSEL is generated at a high level, the redundant word line receiving the select signal RWLSEL at a high level is activated (high level).

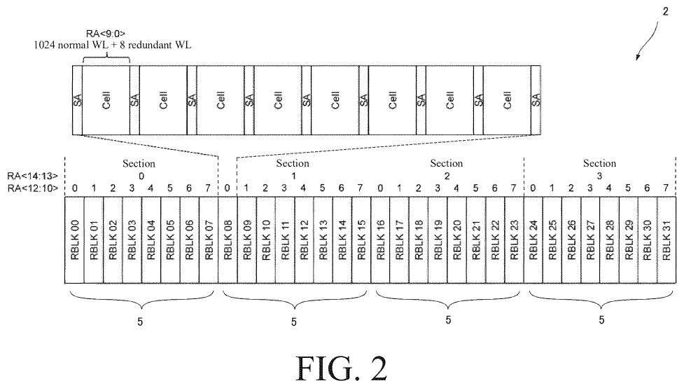

The memory cell array 2 will be described with reference to FIG. 2. Please note that although specific numbers are used for the following description, the present invention is not limited thereto. The memory cell array 2 includes word lines extending along a first direction and column lines extending along a second direction perpendicular to the first direction, and these lines together constitute a memory cell. Each word line and column line may be provided with a redundant word line and a redundant column line that can be used as a backup so that repair can be performed in units of word lines or column lines when a failure occurs. In addition, bit lines are formed along the column lines, and the bit lines are connected to a plurality of memory cells. Please note that detailed drawing of the bit lines and memory cells is omitted in FIG. 2.

The memory cell array 2 is divided into a plurality of segments 5, each segment 5 includes a first predetermined number of normal word lines and a second predetermined number of redundant word lines, and the first predetermined number is greater than the second predetermined number. In the present embodiment, the memory cell array 2 has 32756 normal word lines, 256 redundant word lines, and includes four segments 5. Each segment 5 includes normal word lines and redundant word lines (collectively referred to as word lines), and is set as an region in which only one of the word lines is activated during a refresh operation. In addition, these segments 5 are configured to have the same number of normal word lines and the same number of redundant word lines.

Each segment 5 may be composed of eight row blocks RBLK. The row block RBLK is the region where the word lines of the memory cell array 2 share the bit lines interposed between the sense amplifiers SA. There are 32 row blocks RBLK00 to RBLK31, and each row block RBLK is composed of 1024 normal word lines and 8 redundant word lines. There is no limitation on the number of redundant word lines provided in each row block (RBLK), as long as they are evenly configured in each segment 5. In other words, in the present embodiment, each segment 5 includes 8244 normal word lines and 64 redundant word lines, but they can be equally distributed to each row block RBLK, or, for example, in the segment 5_0, row blocks RBLK00 to RBLK06 do not include redundant word lines, and row block RBLK07 can include 64 redundant word lines.

The address signal RA allocated to such a memory cell array 2 is, for example, has 15 bits, wherein bits <14:13> of the address signal RA can be used to indicate which segment 5, bits <12:10> can be used to indicate which row block RBLK in the segment 5, and bits <9:0> can be used to indicate the addresses of the normal word lines and redundant word lines in each row block RBLK. In addition, in this embodiment, bits <14:13> allocated to indicate the address of the segment 5 in the address signal RA can be set as the first address, and bits <12:0> allocated to indicate the addresses of the normal word lines and redundant word lines can be set as the second address.

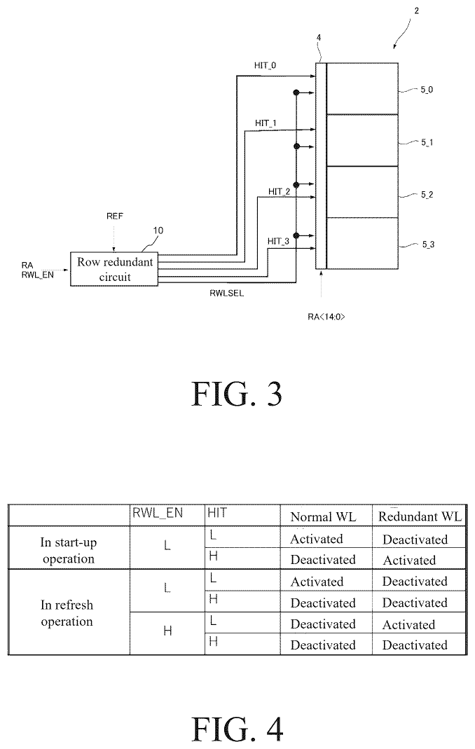

FIG. 3 is a schematic block diagram showing the relationship between the row redundancy circuit 10 and the segments 5. As described above, the refresh status signal REF, the address signal RA, and the redundant enable signal RWL_EN are input to the row redundancy circuit 10, and then the row redundancy circuit 10 generates the inhibit signals HIT, each corresponding to a specific segment, and the select signals RWLSEL based on these signals. Here, the row redundancy circuit 10 generates the inhibit signals HIT (HIT_0 to HIT_3) for segments 5_0 to 5_3, respectively. In addition, the number of select signals RWLSEL generated by the row redundancy circuit 10 is the same as the number of redundant word lines in the memory cell array 2. The row redundancy circuit 10 provides the inhibit signals HIT and the select signals RWLSEL to the segments 5 constituting the memory cell array 2 via the row decoder 4. For example, the inhibit signals HIT_0 to HIT_3 generated by the row redundancy circuit 10 are provided to the segments 5_0 to 5_3, respectively.

Referring to FIG. 4, the active operation and refresh operation of the row redundancy circuit 10 are described. First, the active operation period (normal read and write operation) is described. During the active operation, the row redundancy circuit 10 receives the refresh status signal REF at a low level and the redundancy enable signal RWL_EN at a low level. In this scenario, in the memory cell array 2, the normal word line corresponding to the address signal RA is activated when the row redundancy circuit 10 generates the inhibit signals HIT at a low level during the active operation. Conversely, when a corresponding inhibit signal HIT (any of HIT_0 to HIT_3) is generated at a high level, it indicates that the normal word line corresponding to the address signal RA is defective. As a result, the normal word line corresponding to the address signal RA is not activated, and the corresponding redundant word line is activated. In this embodiment, the redundant word line to be replaced is not limited to the redundant word line in the same segment 5. For example, if a normal word line in segment 5_0 is defective, it can be replaced by a redundant word line in another segment 5, that is, any of the segment 5_1 to segment 5_3.

Next, the refresh operation is described. During the refresh operation, the row redundancy circuit 10 receives a high-level refresh status signal REF, which activates the normal word lines and the redundant word lines one by one in sequence. Specifically, when the row redundancy circuit 10 receives a low-level redundant enable signal RWL_EN, the normal word line is activated in sequence. The row redundancy circuit 10 then generates an inhibit signal HIT for each segment 5 accordingly. In each segment 5, the normal word line corresponding to the address signal RA is activated when the row decoder 4 receives a low-level inhibit signal HIT. When the inhibit signal HIT is at a high level, it indicates that the normal word line corresponding to the address signal RA is defective, and the row decoder 4 deactivates the normal word line and the redundant word line in the corresponding segment 5. In this way, the normal word line will not be replaced by the redundant word line. In addition, when the row redundancy circuit 10 receives a high-level redundant enable signal RWL_EN, the row redundancy circuit 10 generates the inhibit signal HIT for each segment 5 accordingly. In each segment 5, when the row decoder 4 receives a low-level inhibit signal HIT, the normal word line corresponding to the address signal RA is deactivated, and the redundant word line is activated. The row decoder 4 deactivates both the normal word line and the redundant word line in the corresponding segment 5 when the inhibit signal HIT becomes a high level.

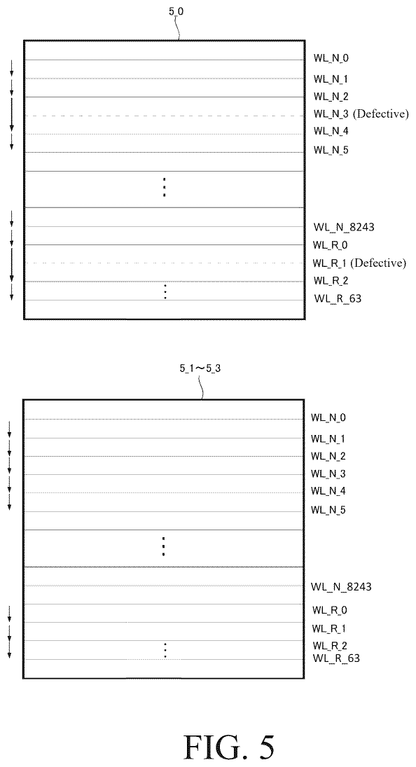

The refresh operation of the present disclosure will be described in more detail with reference to FIG. 5. Here, a case is taken as an example in which the normal word line WL_N_3 and the redundant word line WL_R_1 in the segment 5_0 are defective, and the redundant word line WL_R_0 replaces the normal word line WL_N_3 during the active operation, while all word lines in other segments 5 are non-defective. When the refresh operation starts, the row redundancy circuit 10 receives the redundant enable signal RWL_EN at a low level, and the normal word lines are first activated. At this moment, the row redundancy circuit 10 receives the address signal RA<12:0>, and the word lines with the same address in each segment 5 are activated at the same time. Then, the address signal RA is incremented by an address counter (not shown), thereby sequentially activating the normal word lines WL_N_0 to WL_N_2 in parallel across the segments 5. Therefore, when there is no defect, four normal word lines corresponding to the address signal RA are activated simultaneously in the entire memory cell array 2. In this way, the present embodiment can reduce the time required for the refresh operation.

In other words, if the normal word lines in the segment 5 corresponding to the address signal RA has no defects, the row redundancy circuit 10 will continue to output the inhibit signal HIT at the low level to the row decoder 4, so that the row decoder 4 activates the normal word lines in sequence starting from the normal word line WL_N_0 in each segment 5. When the incremented address signal RA selects the normal word line WL_N_3, the row redundancy circuit 10 will output the inhibit signal HIT at the high level to the row decoder 4, so that all the normal word lines and redundant word lines in the segment 5_0 are not activated. In contrast, because the normal word lines WL_N_3 in the segments 5_1 to 5_3 have no defects, the normal word lines WL_N_3 in the segments 5_1 to 5_3 are activated at the same time. In other words, at this moment, three normal word lines are activated in the entire memory cell array 2. Next, the address signal RA is incremented according to the address counter, and since the normal word lines WL_N_4 in each of the segments 5_0 to 5_3 are not defective, the normal word lines WL_N_4 in these segments 5_0 to 5_3 can be activated simultaneously. In this way, the remaining normal word lines WL_N_5 to WL_N_8243 of each segment 5 can be activated sequentially (when there are no defects).

Similarly, during the refresh operation, when the row redundancy circuit 10 receives the redundant enable signal RWL_EN at a high level, the corresponding redundant word lines will be activated. The address counter enables the redundant word lines WL_R_0 to WL_R_63 in each segment 5 to be activated in sequence, and the entire memory cell array 2 has four redundant word lines activated at the same time. In this case, in the segment 5 where the redundant word line is not defective, the redundant enable signal RWL_EN continues to be input at a high level, and the redundant word lines are sequentially activated starting from the redundancy word line WL_R_0. On the other hand, in the segment 5_0 where the redundancy word line WL_R_1 is defective, when the address signal RA indicates the redundancy word line WL_R_1, the row redundancy circuit 10 outputs a inhibit signal HIT at a high level, and at this moment, all the normal word lines and the redundancy word lines in the segment 5_0 are not activated. Therefore, only three redundant word lines are activated at this moment in the entire memory cell array 2. Then, the address counter increments the address signal RA, and the redundant word line WL_R_2 of the next address is activated because there is no defect in any segment 5. In this way, the remaining redundant word lines of each segment can be activated sequentially (in the case of no defect).

As described above, in the present embodiment, since a dedicated inhibit signal HIT is generated for each segment 5, activation/deactivation control can be performed independently for each segment 5 during the refresh operation, and both the normal word line and the redundant word line in the corresponding segment 5 are deactivated when the inhibit signal HIT is generated at a high level. As a result, during the refresh operation, in the case where the normal word line or the redundant word line is defective, both word lines are deactivated, thereby suppressing unnecessary power consumption. In addition, in conventional semiconductor devices, when a normal memory cell is defective, the redundant memory cell selected for replacement is limited, and the redundancy efficiency is reduced by the factor of N, resulting in poor redundant efficiency and low yield. In contrast, in the present embodiment, during the active operation, when a normal word line is defective, there is no limitation on which segment 5 is to replaced using a redundant word line, so the yield of the semiconductor memory device 1 can be improved. Besides, since activation and replacement of defective normal word lines and defective redundant word lines are not performed within each segment 5 during the refresh operation, the power consumption of the semiconductor memory device 1 can be reduced.

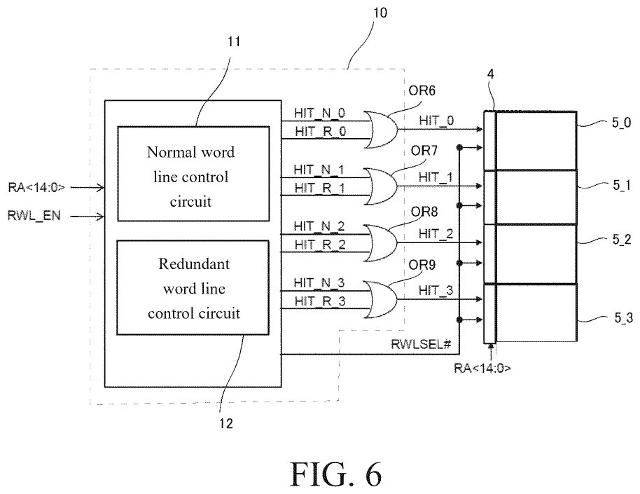

As shown in FIGS. 6 to 8, the row redundancy circuit 10 of the present embodiment includes a normal word line control circuit 11 and a redundant word line control circuit 12. The normal word line control circuit 11 is configured to control whether to replace the normal word line with the redundant word line, and operates when the redundant enable signal RWL_EN is at a low level. The normal word line control circuit 11 generates a normal word line inhibit signal HIT_N and a select signal RWLSEL based on the address signal RA and the redundant enable signal RWL_EN, wherein the normal word line inhibit signal HIT_N indicates that the activation of the normal word line is inhibited.

The redundant word line control circuit 12 is used to deactivate the redundant word line that is defective when the redundant word line is defective, and operates when the redundant enable signal RWL_EN is at a high level. The redundant word line control circuit 12 generates a redundant word line inhibit signal HIT_R based on the address signal RA and the redundant enable signal RWL_EN. The redundant word line inhibit signal HIT_R indicates that the redundant word line is inhibited from being activated. The redundant word line inhibit signal HIT_R stops the activation of the redundant word line when the redundant word line corresponding to the address signal RA is defective.

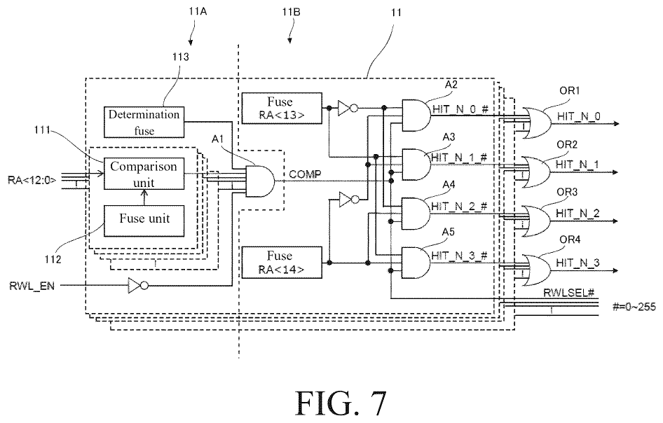

As shown in FIG. 7, the normal word line control circuit 11 includes a word line determination circuit 11A and a segment determination circuit 11B. The word line determination circuit 11A is configured to compare the input address signal RA with fuse information and generate an output signal COMP which indicates whether the normal word line corresponding to the address signal RA is defective. The segment determination circuit 11B is configured to determine whether the normal word line of each segment 5 is defective based on the output signal COMP from the word line determination circuit 11A, and generate a normal word line inhibit signal HIT_N.

In specific, the word line determination circuit 11A may include a comparison unit 111, a fuse information unit 112, and a determination fuse 113. The comparison unit 111 is configured to compare the address signal RA<12:0> input to the normal word line control circuit 11 with the address of the normal word line to be replaced which is stored in the fuse information unit 112, and a signal indicating the comparison result of whether the normal word line corresponding to the address signal RA<12:0> is defective is input to the AND circuit A1. In addition, 13 bits may be extracted from the address signal RA<14:0> (shown in FIG. 6) input to the row redundancy circuit 10, and used as the address signal RA<12:0> input to the normal word line control circuit 11. The address signal bits RA<14:13>, which indicate the segment 5, are not input to the comparison unit 111.

In addition, the signal which indicates whether the determination fuse 113 is blown (that is, whether a redundant word line should replace a normal word line) is input to an AND circuit A1. The AND circuit A1 further receives the inverted redundant enable signal RWL_EN. Based on these input signals, the AND circuit A1 performs a logical AND operation and outputs the output signal COMP. That is, the output signal COMP indicates whether the normal word line in the segment 5 is defective when the normal word line is activated during the refresh operation. Therefore, the output signal COMP is output at a high level when the redundant enable signal RWL_EN is input at a low level, the address signal RA<12:0> matches the address stored in the fuse information unit 112, and it is further determined that the determination fuse 113 is blown.

The output signal COMP is input to AND circuits A2 to A5, respectively. In addition, the output signal COMP is input to segment 5 as a select signal RWLSEL, wherein the output signal COMP is input to the segment of the normal word line with a defect at a high level and is input to other segments at a low level. The fuse information of the address signal RA<14:13> is decoded and input to the AND circuits A2 to A5, respectively, for selecting a segment. In specific, the inverted signal representing the fuse information corresponding to the address signal RA<13> and the inverted signal representing the fuse information corresponding to the address signal RA<14> are input to the AND circuit A2. The signal representing the fuse information corresponding to the address signal RA<13> and the inverted signal representing the fuse information corresponding to the address signal RA<14> are input to the AND circuit A3. The inverted signal representing the fuse information corresponding to the address signal RA<13> and the signal representing the fuse information corresponding to the address signal RA<14> are further input to the AND circuit A4. The signal representing the fuse information corresponding to the address signal RA<13> and the signal representing the fuse information corresponding to the address signal RA<14> are further input to the AND circuit A5.

Each of the AND circuits A2 to A5 outputs temporary normal word line inhibit signals HIT_N_0_# to HIT_N_3_# according to the output signal COMP and the address signal RA<14:13>. The row redundancy circuit 10 has normal word line control circuits 11 whose number matches the number of redundant word lines in the memory cell array 2, and these normal word line control circuits 11 generate and output the temporary normal word line inhibit signals HIT_N_0_# to HIT_N_3_# in a similar manner. Therefore, this # matches the number of redundant word lines in the memory cell array 2. In the present embodiment, # is any number between 0 and 255. These temporary normal word line inhibit signals HIT_N_0_0 to HIT_N_0_255 are input to the OR circuit OR1. Similarly, these temporary normal word line inhibit signals HIT_N_1_# to HIT_N_3_# are respectively input to the OR circuits OR2 to OR4, and normal inhibit signals HIT_N_0 to HIT_N_3 are output from the OR circuits OR1 to OR4. When the output signal COMP is output at a high level, one of the normal word line inhibit signals HIT_N_0 to HIT_N_3 becomes high level.

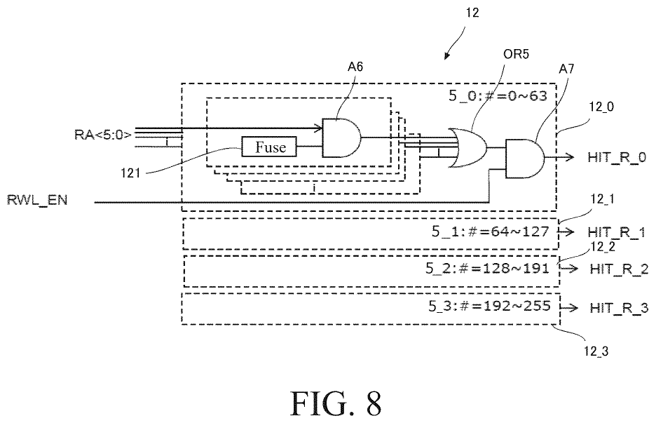

As shown in FIG. 8, the redundant word line control circuit 12 includes redundant word line control circuits 12_0 to 12_3 corresponding to the segments 5. However, since the redundant word line control circuits 12 of each segment 5 have the same configuration, only the redundant word line control circuit 12_0 of the segment 5_0 is described as an example. The redundant word line control circuit 12 receives the address signal RA<5:0> indicating the redundant word line in the address signal RA and the redundant enable signal RWL_EN. The redundant word line control circuit 12 has a determination fuse 121 for setting the redundant word line corresponding to the address signal RA to be deactivated, and when the redundant word line is defective, the determination fuse 121 is cut off. The AND circuit A6 receives and performs an AND operation on the address signal RA<5:0> and the signal indicating the state of the determination fuse 121, and outputs the result of the operation to the OR circuit OR5. The number of fuses 121, AND circuits A6, and OR circuits OR5 may be equal to the number of redundant word lines in segment 5_0, that is, 64. The AND circuit A7 receives and performs an AND operation on the output of each OR circuit OR5 and the redundant enable signal RWL_EN, and outputs the result of the operation as the redundant word line inhibit signal HIT_R_0. Similarly, corresponding to each of the segments 5_1 to 5_3, the redundant word line control circuits 12_1 to 12_3 generate redundant word line inhibit signals HIT_R_1 to HIT_R_3, respectively.

Referring to FIG. 6, the row redundancy circuit 10 further includes OR circuits OR6 to OR9. The normal word line inhibit signal HIT_N (HIT_N_0 to HIT_N_3) and the redundant word line inhibit signal HIT_R (HIT_R_0 to HIT_R_3) corresponding to each segment 5 are input to the OR circuits OR6 to OR9 to perform OR operations to generate the inhibit signal HIT (HIT_0 to HIT_3) for each of the segments 5 (5_0 to 5_3). That is, when the normal word line inhibit signals HIT_N or the redundant word line inhibit signals HIT_R becomes high level, the inhibit signal HIT is output at a high level, and all word lines in the segment 5 receiving the high level inhibit signal HIT become deactivated.

In this way, the inhibit signal HIT of different segments is generated separately and input to the corresponding segment 5. Therefore, during the refresh operation, the word lines corresponding to the address signal RA can be activated simultaneously in multiple segments 5. However, if a word line in a segment 5 is defective, all word lines in the segment will be deactivated, thereby suppressing unnecessary power consumption.

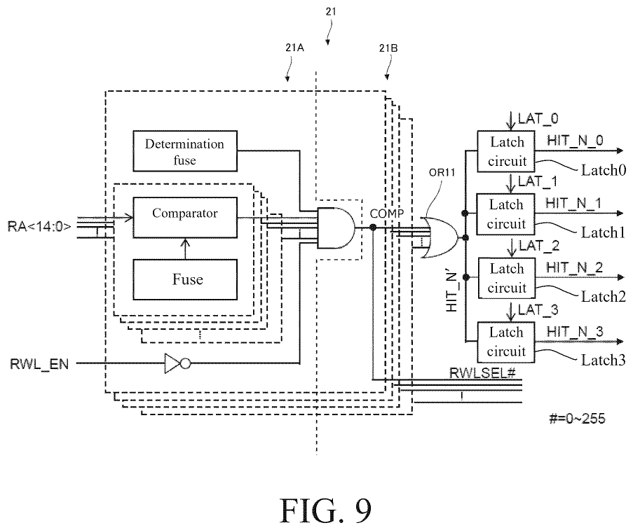

It should be noted that the normal word line control circuit and the redundant word line control circuit of the present invention only need to be capable of achieving the above functions and are not limited to the examples described in the above embodiments. For example, a modified example of the normal word line control circuit of the present invention can be configured as shown in FIG. 9.

As shown in FIG. 9, the normal word line control circuit 21 includes a word line determination circuit 21A and a segment determination circuit 21B, which can realize the same function as the normal word line control circuit 11. The word line determination circuit 21A generates an output signal COMP to indicate whether the normal word line corresponding to the address signal RA is defective. The segment determination circuit 21B determines whether the normal word line in each segment 5 is defective by latching the output signal COMP from the word line determination circuit 21A, and generates a normal word line inhibit signal HIT_N for inhibiting the activation of the normal word line. The word line determination circuit 21A is the same as the word line determination circuit 11A, so its description will be omitted.

In the normal word line control circuit 21, the number of output signals COMP generated by the word line determination circuit 21A is equal to the number of redundant word lines (that is, 256), and all the output signals COMP are input to the OR circuit OR11 for OR operation and output as the temporary inhibit signal HIT_N′. The temporary inhibit signal HIT_N is respectively input to a plurality of latch circuits Latch0 to Latch3 (the number of which is the same as that of the segments), and latched corresponding to each of the segments 5 (5_0 to 5_3) according to the latch signals LAT_0 to LAT_3 to generate normal word line inhibit signals HIT_N_0 to HIT_N_3.

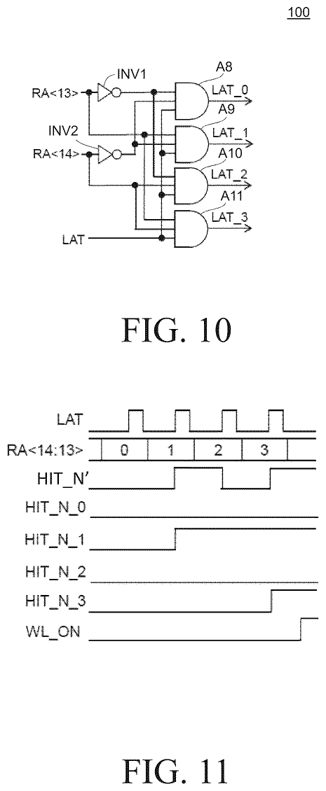

FIG. 10 shows a latch signal generating circuit 100 according to an embodiment of the present invention. The latch signal generating circuit 100 includes a plurality of inverters INV1, INV2 and a plurality of AND circuits A8 to A11. The address signal RA<14>, the address signal RA<13> (or its inverted signal) and the latch signal LAT are input to each of the AND circuits A8 to A11 to generate latch signals LAT_0-LAT_3 corresponding to each of the segments 5_0-5_3. The latch signals LAT_0 to LAT_3 are input to the latch circuits Latch0-Latch3.

For example, FIG. 11 shows a timing diagram according to the embodiment of FIG. 10 when the normal word lines of segments 5_1 and 5_3 are defective, wherein the temporary inhibit signal HIT_N′ becomes high level in response to the latch signal LAT_1 and the latch signal LAT_3.

With respect to the temporary inhibit signal HIT_N′, when the latch signals LAT_0 to LAT_3 of the segments 5_0 to 5_3 based on the address signal RA<14:13> are input, among the normal word line inhibit signals HIT_N_0 to HIT_N_3, only the normal word line inhibit signals HIT_N_1 and HIT_N_3 is output at high levels. The normal word line control circuit 21 is configured according to such goal. In addition, as shown in FIG. 11, the word line activation signal WL_ON output from the control circuit 3 is activated when the latch signal LAT completes the output at high level 4 times. The activation of the word line starts when this word line activation signal WL_ON is input to the row decoder 4 at a high level.

In the aforementioned embodiments, the semiconductor memory device is DRAM as an example, but the present invention is not limited to this. For example, the semiconductor memory device can be SRAM (Static Random Access Memory), Flash memory, or other semiconductor memory devices that require refresh operations.

The above-described embodiments and variants are described for easy understanding of the present invention, but are not intended to limit the present invention. Therefore, each element disclosed in the above embodiments and variants is intended to include all design changes and equivalents within the technical scope of the present invention.

What is claimed is:

1. A semiconductor memory device, comprising:
a memory cell array having a plurality of segments, each segment having a plurality of normal word lines and a plurality of redundant word lines; and
a row redundancy circuit configured to activate non-defective normal word lines and non-defective redundant word lines during a refresh operation,
wherein activation and replacement of defective normal word lines and defective redundant word lines are not performed within each segment during the refresh operation.

2. The semiconductor memory device as claimed in claim 1, wherein the segments include a first segment and a second segment, the first segment has a plurality of first normal word lines and a plurality of first redundant word lines, and the second segment has a plurality of second normal word lines and a plurality of second redundant word lines;
during the refresh operation, the row redundancy circuit is further configured to:
generate a first inhibit signal and a second inhibit signal respectively for the first segment and the second segment;
according to the first inhibit signal and the second inhibit signal, activate one of the first normal word lines that is not defective and one of the second normal word lines that is not defective simultaneously or activate one of the first redundant word lines that is not defective and one of the second redundant word lines that is not defective simultaneously; and deactivate the first normal word lines that are defective, the second normal word lines that are defective, the first redundant word lines that are defective, and the second redundant word lines that are defective.

3. The semiconductor memory device as claimed in claim 2, wherein the number of the first normal word lines is greater than that of the first redundant word lines, and the number of the second normal word lines is greater than that of the second redundant word lines.

4. The semiconductor memory device as claimed in claim 2, wherein the row redundancy circuit is further configured to:
receive an address signal, wherein the address signal includes a first address for indicating the first segment or the second segment, and a second address for indicating the first normal word lines, the second normal word lines, the first redundant word lines, or the second redundant word lines; and
during the refresh operation, activate one of the first normal word lines that is not defective and one of the second normal word lines that is not defective, or activate one of the first redundant word lines that is not defective and one of the second redundant word lines that is not defective, according to the second address, at the same time.

5. The semiconductor memory device as claimed in claim 4, wherein during the refresh operation, the row redundancy circuit is further configured to:
receive a refresh status signal at a low level and a redundant enable signal at a low level, and
generate the first inhibit signal, the second inhibit signal and a select signal according to the address signal, the refresh status signal and the redundant enable signal;
wherein when the first inhibit signal or the second inhibit signal corresponding to the address signal is at a high level, the select signal is generated at a high level to activate one of the first redundant word lines or one of the second redundant word lines which receives the select signal and is not defective.

6. The semiconductor memory device as claimed in claim 4, wherein the row redundancy circuit includes:
a normal word line control circuit configured to generate a first normal word line inhibit signal for inhibiting activation of defective ones of the first normal word lines, and a second normal word line inhibit signal for inhibiting activation of defective ones of the second normal word lines; and
a redundant word line control circuit configured to generate a first redundant word line inhibit signal for inhibiting activation of defective ones of the first redundant word lines, and a second redundant word line inhibit signal for inhibiting activation of defective ones of the second redundant word lines;
wherein when the first normal word line inhibit signal or the first redundant word line inhibit signal is activated, the row redundancy circuit generates the first inhibit signal at a high level, and when the second normal word line inhibit signal or the second redundant word line inhibit signal is activated, the row redundancy circuit generates the second inhibit signal at a high level.

7. The semiconductor memory device as claimed in claim 6, wherein the normal word line control circuit includes:
a word line determination circuit configured to compare the address signal with fuse information to generate an output signal indicating whether one of the first normal word lines and the second normal word lines corresponding to the address signal is defective; and
a segment determination circuit configured to determine whether one of the first normal word lines and the second normal word lines corresponding to the address signal is defective according to the output signal from the word line determination circuit, and generate the first normal word line inhibit signal at a high level or the second normal word line inhibit signal at a high level when it is determined to be defective.

8. The semiconductor memory device as claimed in claim 7, wherein the number of the segment determination circuits is more than one and is the same as that of the redundant word lines of the memory cell array; and the segment determination circuits generate multiple temporary normal word line inhibit signals according to the fuse information, the decoded fuse information and the output signal.

9. The semiconductor memory device as claimed in claim 7, wherein the segment determination circuit latches the output signal according to the address signal to generate the first normal word line inhibit signal and the second normal word line inhibit signal.

10. The semiconductor memory device as claimed in claim 8, wherein the segment determination circuits include a plurality of AND circuits, each of the AND circuits performing AND operation on the output signal, the fuse information or the decoded fuse information to generate each of the temporary normal word line inhibit signals;
wherein the temporary normal word line inhibit signals corresponding to the first segment are input to a first OR circuit to generate the first normal word line inhibit signal, and the temporary normal word line inhibit signals corresponding to the second segment are input to a second OR circuit to generate the second normal word line inhibit signal.

11. The semiconductor memory device as claimed in claim 9, wherein the segment determination circuit has a first latch circuit corresponding to the first segment and a second latch circuit corresponding to the second segment, the output signal is input to the first latch circuit and the second latch circuit, the segment determination circuit latches the output signal according to the address signal to generate the first normal word line inhibit signal and the second normal word line inhibit signal.

12. The semiconductor memory device as claimed in claim 7, wherein the redundant word line control circuit compares the address signal with the fuse information to determine whether the first redundant word lines and the second redundant word lines are defective, the first redundant word line inhibiting signal is output at a high level when one of the first redundant word lines corresponding to the address signal is defective, and the second redundant word line inhibiting signal is output at a high level when one of the second redundant word lines corresponding to the address signal is defective.

13. The semiconductor memory device as claimed in claim 1, wherein the semiconductor memory device is Dynamic Random Access Memory (DRAM).

14. The semiconductor memory device as claimed in claim 4, wherein the row redundancy circuit, during the refresh operation, is further configured to:
receive a refresh status signal at a high level;
in response to receiving a redundancy enable signal at a low level, based on the address signal, the first inhibit signal at a low level and the second inhibit signal at a low level, sequentially activate the ones of the first normal word lines that are non-defective in the first segment starting from the position corresponding to the address signal, and in parallel, sequentially activate the ones of the second normal word lines that is non-defective in the second segment starting from the position corresponding to the address signal;
in response to receiving the redundancy enable signal at a high level, based on the address signal, the first inhibit signal at a low level and the second inhibit signal at a low level, sequentially activate the ones of the first redundant word lines that are non-defective in the first segment starting from the position corresponding to the address signal, and in parallel, sequentially activate the ones of the second redundant word lines that are non-defective in the second segment starting from the position corresponding to the address signal;
wherein during the period of receiving the redundant enable signal at a low level, the defective ones among the first normal word lines are inhibited from being activated when receiving the first inhibit signal at a high level, and when receiving the second inhibit signal at a high level, the defective ones among the second normal word lines are inhibited from being activated when receiving the second inhibit signal at a high level;
wherein during the period of receiving the redundant enable signal at a high level, the defective ones of the first redundant word lines are inhibited from being activated when receiving the first inhibit signal at a high level, and the defective ones of the second redundant word lines are inhibited from being activated when receiving the second inhibit signal at a high level.

15. A refresh control method for a semiconductor memory device, comprising:
configuring a memory cell array to include a plurality of segments, each of the segments has a plurality of normal word lines and a plurality of redundant word lines;
during a refresh operation, activating non-defective normal word lines and non-defective redundant word lines by a row redundancy circuit, wherein activation and replacement of defective normal word lines and defective redundant word lines are not performed in each of the segments.

16. The refresh control method as claimed in claim 15, wherein the segments include a first segment and a second segment, the first segment has a plurality of first normal word lines and a plurality of first redundant word lines, and the second segment has a plurality of second normal word lines and a plurality of second redundant word lines, and the method further comprises the steps of:
during the refresh operation, generating a first inhibit signal and a second inhibit signal for the first segment and the second segment, respectively;
wherein according to the first inhibit signal and the second inhibit signal, simultaneously activating one of the non-defective first normal word lines and one of the non-defective second normal word lines, or simultaneously activating one of the non-defective first redundant word lines and one of the non-defective second redundant word lines, and deactivating defective ones of the first normal word lines, defective ones of the second normal word lines, defective ones of the first redundant word lines, and defective ones of the second redundant word lines.

17. The refresh control method as claimed in claim 16, further comprising the steps of:
receiving an address signal, wherein the address signal includes a first address for indicating the first segment or the second segment, and a second address for indicating the first normal word lines, the second normal word lines, the first redundant word lines, or the second redundant word lines;
wherein during the refresh operation, simultaneously activating one of the first normal word lines that is not defective and one of the second normal word lines that is not defective according to the second address, or simultaneously activating one of the first redundant word lines that is not defective and one of the second redundant word lines that is not defective.

18. The refresh control method as claimed in claim 17, wherein the step of generating the first inhibit signal and the second inhibit signal for the first segment and the second segment respectively, further includes:
generating a first normal word line inhibit signal for inhibiting activation of defective ones of the first normal word lines, and a second normal word line inhibit signal for inhibiting activation of defective ones of the second normal word lines; and
generating a first redundant word line inhibit signal for inhibiting activation of defective ones of the first redundant word lines, and a second redundant word line inhibit signal for inhibiting activation of defective ones of the second redundant word lines;
wherein the first inhibit signal is generated at a high level when the first normal word line inhibit signal or the first redundant word line inhibit signal is activated, and the second inhibit signal is generated at a high level when the second normal word line inhibit signal or the second redundant word line inhibit signal is activated.

19. The refresh control method as claimed in claim 18, wherein the step of generating the first normal word line inhibit signal and the second normal word line inhibit signal further includes:
comparing the address signal with fuse information to generate an output signal indicating whether one of the first normal word lines and the second normal word lines corresponding to the address signal is defective; and
determining whether one of the first normal word lines and the second normal word lines corresponding to the address signal is defective based on the output signal, and generating the first normal word line inhibit signal at a high level or the second normal word line inhibit signal at a high level when determining that it is defective.

20. The refresh control method as claimed in claim 17, wherein during the refresh operation, the method further comprises:
receiving a refresh status signal at a high level;
in response to receiving a redundant enable signal at a low level, based on the address signal, the first inhibit signal at a low level and the second inhibit signal at a low level, sequentially activating the non-defective ones of the first normal word lines in the first segment starting from the position corresponding to the address signal, and in parallel, sequentially activating the non-defective ones of the second normal word lines in the second segment starting from the position corresponding to the address signal;
in response to receiving the redundant enable signal at a high level, based on the address signal, the first inhibit signal at a low level and the second inhibit signal at a low level, sequentially activating the non-defective ones of the first redundant word lines in the first segment starting from the position corresponding to the address signal, and in parallel, sequentially activating the non-defective ones of the second redundant word lines in the second segment starting from the position corresponding to the address signal;
wherein during the period of receiving the redundant enable signal at a low level, the defective ones of the first normal word lines are inhibited from being activated when receiving the first inhibit signal at a high level, and the defective ones of the second normal word lines are inhibited from being activated when receiving the second inhibit signal at a high level;
wherein during the period of receiving the redundant enable signal at a high level, the defective ones of the first redundant word lines are inhibited from being activated when receiving the first inhibit signal at a high level, and the defective ones of the second redundant word lines are inhibited from being activated when receiving the second inhibit signal at a high level.
